(19) United States
(12) Patent Application Publication
(10) Pub. No.: US 2026/0130271 A1
(43) Pub. Date: May 7, 2026

(54) SEMICONDUCTOR PACKAGE

(71) Applicant: Taiwan Semiconductor Manufacturing Company, Ltd., Hsinchu (TW)

(72) Inventors: Mao-Yen Chang, Kaohsiung City (TW); Wei-Jie Huang, Hsinchu (TW); Jeng-An Wang, Hsinchu City (TW); Hao-Cheng Hou, Hsinchu City (TW); Tsung-Ding Wang, Tainan (TW); Cheng-Yu Kuo, Kaohsiung City (TW); Hsien-Chien Hsieh, Taichung City (TW); Yao-Jen Chang, Hsinchu (TW); Ping-Kang Huang, Chiayi City (TW); Hsiu-Jen Lin, Hsinchu County (TW)

(73) Assignee: Taiwan Semiconductor Manufacturing Company, Ltd., Hsinchu (TW)

(21) Appl. No.: 18/940,790

(22) Filed: Nov. 7, 2024

(51) Int. Cl. H01L 23/31; H01L 23/00; H01L 23/29; H01L 23/498; H01L 23/538; H01L 25/16

(52) U.S. Cl. CPC H10W 74/121; H10W 70/611; H10W 70/635; H10W 70/65; H10W 74/117; H10W 74/473; H10W 90/00; H10W 90/401; H10W 72/252; H10W 74/15; H10W 90/724; H10W 90/734

(57) ABSTRACT

A semiconductor package includes a first interconnect component, a second interconnect component and a third encapsulant. The first interconnect component includes a first encapsulant. The second interconnect component is laterally spaced apart from the first interconnect component and includes a second encapsulant. The third encapsulant laterally encapsulates the first interconnect component and the second interconnect component. The first encapsulant includes a first filler having a first average size, and the second encapsulant includes a second filler having a second average size different from the first average size.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 9 illustrate cross-sectional views of intermediate steps during a process for forming a semiconductor package in accordance with some embodiments of the present disclosure.

FIG. 10 is a schematic cross-sectional view of another semiconductor package in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein is related to a semiconductor package including two or more interconnect components. The interconnect components may include electrical routing, through vias, integrated devices such as integrated passive devices (IPDs) or local routing structures, or the like. Semiconductor devices may be attached to the two or more interconnect components. In some cases, by using multiple interconnect components in a semiconductor package as described herein, heat dissipation and/or electrical performances of the semiconductor devices may be improved, reliability of at least one of the interconnect components may be improved, and/or the yield may be increased. For example, by integrate an integrated passive device such as an integrated voltage regulator into one of the interconnect components, heat dissipation and/or electrical performances of the semiconductor devices may be improved. Additionally, by changing the method and/or material for forming the encapsulant in the interconnect component including the integrated passive device, voids generated at the interface between the encapsulant and the underlying component/layer due to significant temperature change during the manufacturing process (e.g., a post reflow process or a ball mount process) and/or reliability test process may be reduced, thereby improving reliability and/or increasing yield. Different types of interconnect structures may be used within the same semiconductor package, which can allow for design flexibility and performance improvements.

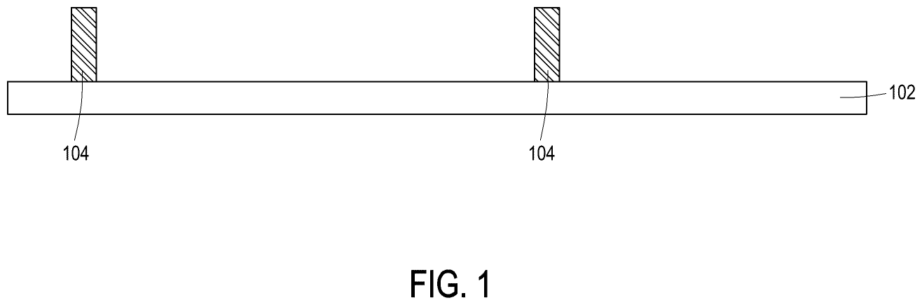

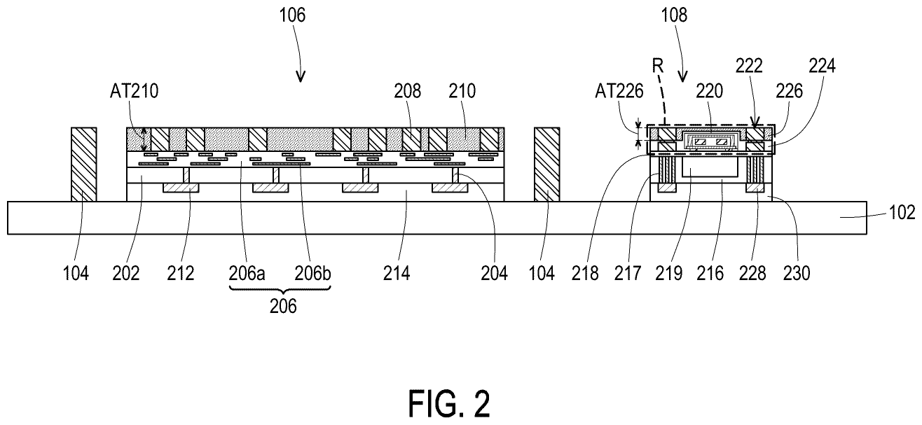

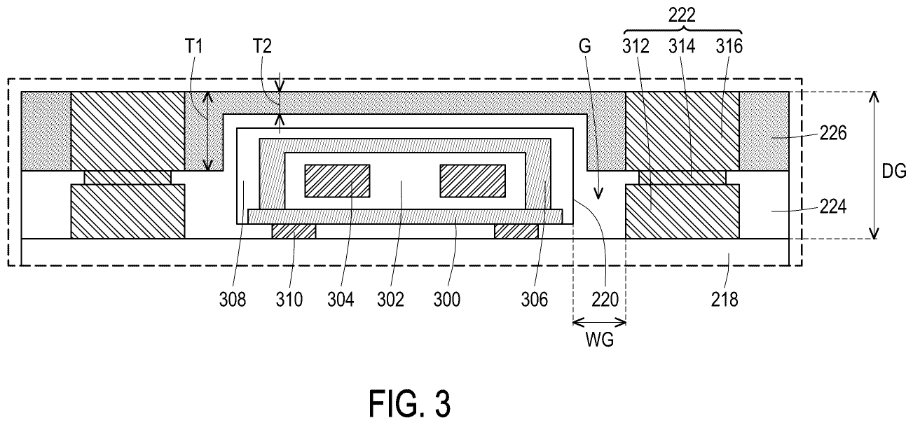

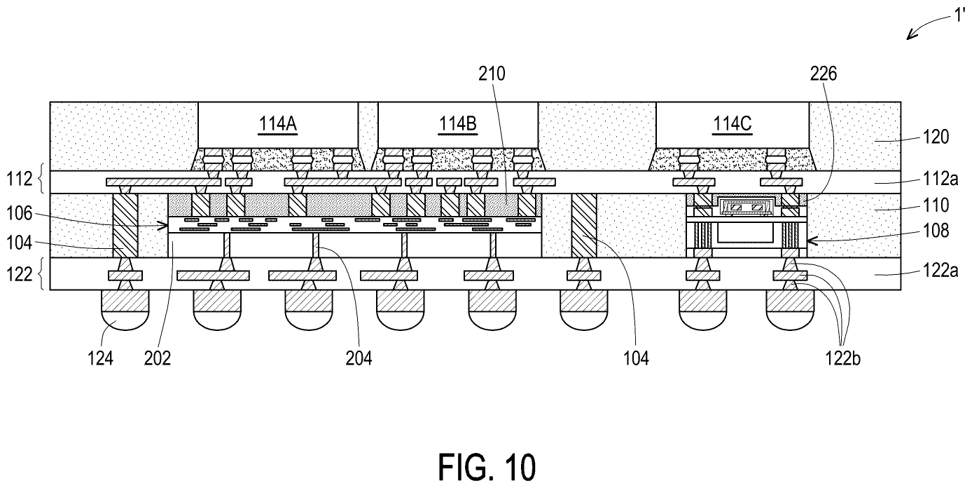

FIG. 1 through FIG. 9 illustrate cross-sectional views of intermediate steps during a process for forming a semiconductor package in accordance with some embodiments of the present disclosure, wherein FIG. 3 is an enlarged schematic diagram of region R in FIG. 2. FIG. 10 is a schematic cross-sectional view of another semiconductor package in accordance with some embodiments of the present disclosure.

Referring to FIG. 1, a first carrier substrate 102 is provided. The first carrier substrate 102 may be a glass carrier substrate, a ceramic carrier substrate, or the like. The first carrier substrate 102 may be a wafer, such that multiple semiconductor packages can be formed on the first carrier substrate 102 simultaneously.

Through vias 104 are formed on the first carrier substrate 102. As an example to form the through vias 104, a seed layer (not shown) is formed over the first carrier substrate 102. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, physical vapor deposition (PVD) or the like. A photoresist is formed and patterned on the seed layer. The photoresist may be formed by spin coating or the like and may be exposed to light for patterning. The pattern of the photoresist corresponds to the through vias 104. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and the conductive material form the through vias 104. In other embodiments, a seed layer is not used.

In some embodiments, although not shown, a release layer is formed on the first carrier substrate 102 prior to forming the through vias 104. The release layer may be formed of a polymer-based material, which may be removed along with the first carrier substrate 102 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. The release layer may be dispensed as a liquid and cured, may be a laminate film laminated onto the first carrier substrate 102, or may be the like. The top surface of the release layer may be leveled and may have a high degree of planarity.

Referring to FIG. 2, a first interconnect component 106 and a second interconnect component 108 are disposed on the first carrier substrate 102. For example, the first interconnect component 106 and the second interconnect component 108 are placed on the first carrier substrate 102 through pick and place processes. In some embodiments, the first interconnect component 106 and the second interconnect component 108 are different types of interconnect components. For example, the first interconnect component 106 is a bridge die (e.g., a local silicon interconnect (LSI die), and the second interconnect component 108 is a multifunctional (e.g., dual-functional) semiconductor die having two or more functional dies or having active devices and passive devices, but not limited thereto. In the embodiments in which the first carrier substrate 102 is a wafer, such that multiple first interconnect component 106 and multiple second interconnect component 108 can be disposed on the first carrier substrate 102.

As an example of the bridge die, the first interconnect component 106 includes a substrate 202 having through-substrate openings that vertically extend through the substrate 202, a dielectric liner (not shown) disposed on sidewalls of the through-substrate openings to provide electrical isolation for through-substrate via structures 204 located in the through-substrate openings, an interconnect structure 206 (e.g., a redistribution structure) having dielectric material layers 206a and conductive features 206b embedded in the dielectric material layers 206a and electrically connected to the through-substrate via structures 204, through vias 208 disposed on and electrically connected to the interconnect structure 206, an encapsulant 210 (also referred to as “first encapsulant”) laterally encapsulates the through vias 208, pads 212 disposed below the substrate 202 and electrically connected to the through-substrate via structures 204 and an encapsulant 214 disposed below the substrate 202 and encapsulates the pads 212.

The substrate 202 may include silicon, doped or undoped, or an active layer of a semiconductor-on-insulator (SOI) substrate. The substrate 202 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; the like; or combinations thereof. In some embodiments, the substrate 202 may include a ceramic material, a polymer film, a magnetic material, the like, or a combination thereof. Other substrates, such as multi-layered or gradient substrates, may also be used.

In some embodiments, the first interconnect component 106 may include active or passive devices. In some embodiments, the first interconnect component 106 may be free of active or passive devices and may only be used for routing of electrical signals. In the embodiments in which active or passive devices are included, devices (not shown) may be formed at the front surface (a surface of the substrate 202 that faces the interconnect structure 206) of the substrate 202. The devices may include active devices (e.g., transistors, diodes, or the like), passive devices (e.g., capacitors, resistors, inductors, or the like), or combinations thereof. An inter-layer dielectric (ILD; not shown) may be between the substrate 202 and the interconnect structure 206 to surround and cover the devices. The ILD may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like. Conductive plugs (not shown) may extend through the ILD and electrically and physically couple the devices. For example, when the devices are transistors, the conductive plugs may couple the gates and source/drain regions of the transistors. The conductive plugs may be formed of tungsten, cobalt, nickel, copper, silver, gold, aluminum, the like, or combinations thereof.

The interconnect structure 206 is over the ILD and the conductive plugs. The interconnect structure 206 interconnects the devices and/or provides electrical routing and connection between through vias 208. The dielectric material layers 206a of the interconnect structure 206 may include low-k dielectric layers. The conductive features 206b of the interconnect structure 206 may include conductive lines and/or conductive vias and may be formed using a suitable process, such as a damascene process. In the embodiments in which devices are included, the conductive features 206b of the interconnect structure 206 are electrically coupled to the devices by the conductive plugs. Although the interconnect structure 206 is illustrated with only three layers of conductive features 206b, in other embodiments more or fewer layers of conductive features 206b may be included.

The through vias 208 may also be referred to as connectors or conductive pillars. The through vias 208 may be formed by a method and a material similar to those of the through vias 104. The through vias 208 electrically couple the respective integrated circuits of the interconnect structure 206.

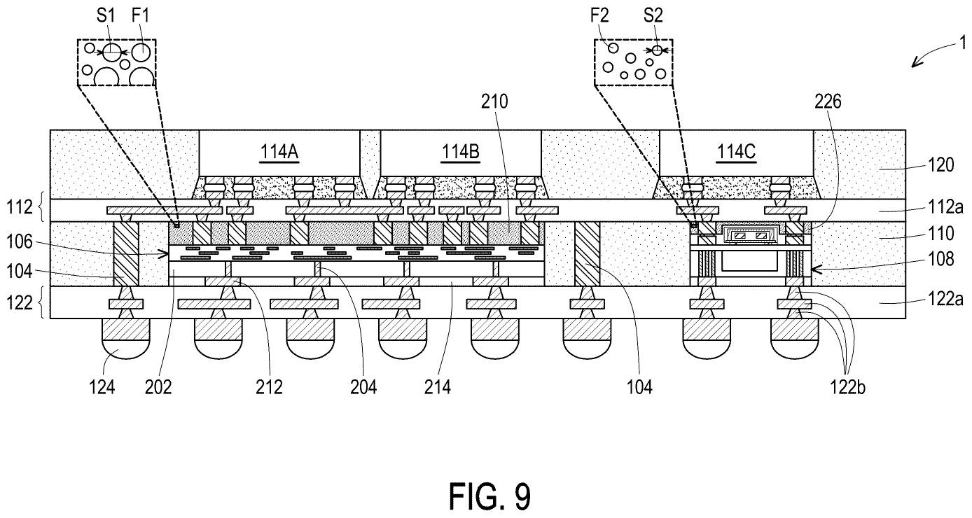

The encapsulant 210 encapsulates the through vias 208. The encapsulant 210 may include a molding compound, such as a liquid type molding compound (e.g., polyimide (PI)). The encapsulant 210 may be applied in a liquid form and then subsequently be hardened (i.e., cured) to have sufficient stiffness and mechanical strength. In some embodiments, the encapsulant material (including polyimide, first fillers, hardener, and other additives) is formed on the interconnect structure 206 and cover the through vias 208 through a coating process (e.g., a spin coating process), and then the encapsulant material is hardened through a curing process. Afterwards, a planarization process (e.g., a mechanical grinding process and/or a chemical mechanical polishing process) is performed on the cured encapsulant material to expose top surfaces of the through vias 208. After the planarization process, top surfaces of the through vias 208 may be level or coplanar with the top surface of the encapsulant 210. In some embodiments, the filler material (e.g., first fillers F1 shown in FIG. 9) of the encapsulant 210 has a first average size (e.g., average particle size S1) that is larger than 5 μm, such as 25 μm, but not limited thereto.

The pads 212 electrically and physically couple the through-substrate via structures 204 and embedded in the encapsulant 214. The pads 212 and the interconnect structure 206 are disposed on opposite sides of the substrate 202, respectively. The pads 212 may be formed by a method and a material similar to those of the through vias 104. The pads 212 electrically couple the respective integrated circuits of the interconnect structure 206 through the through-substrate via structures 204.

The encapsulant 214 may be a molding compound, a molding underfill, a resin (such as an epoxy resin), glue, or the like. In some embodiments, the encapsulation material is formed by an over-molding process, such that not only sidewall surfaces of the pads 212 but also surfaces of the pads 212 away from the substrate 202 are encapsulated/covered by the encapsulant 214. In some embodiments, the encapsulation material is formed by at least one of a compression molding process, an immersion molding process and a transfer molding process. In some embodiments, the encapsulation material may require a curing process. In some embodiments, coefficient of thermal expansion (CTE) of the encapsulant 214 is similar or equal to coefficient of thermal expansion of the encapsulant 210 to improve warpage problem.

As an example of the multifunctional (e.g., dual-functional) semiconductor die, the second interconnect component 108 includes a substrate 216 having through-substrate openings that vertically extend through the substrate 216 and a blind hole that vertically extend from a surface of the substrate 216 to a point inside the substrate 216, a dielectric liner (not shown) disposed on sidewalls of the through-substrate openings to provide electrical isolation for through-substrate via structures 217 located in the through-substrate openings, a semiconductor die 219 disposed in the blind hole of the substrate 216, an interconnect structure 218 (e.g., a back end of line (BEOL) interconnect) disposed on the substrate 216 and the semiconductor die 219 and having dielectric material layers (not shown) and conductive features (not shown) embedded in the dielectric material layers and electrically connected to the through-substrate via structures 217 and the semiconductor die 219, an integrated passive device 220 disposed on and electrically connected to the interconnect structure 218, via structures 222 disposed on and electrically connected to the interconnect structure 218, a passivation layer 224 disposed on the interconnect structure 218 and covers the integrated passive device 220 and a portion of the via structures 222, an encapsulant 226 (also referred to as “second encapsulant”) laterally surrounds the integrated passive device 220 and the via structure 222, pads 228 disposed below the substrate 216 and electrically connected to the through-substrate via structures 217 and an encapsulant 230 disposed below the substrate 216 and encapsulates the pads 228.

The substrate 216 may include silicon, doped or undoped, or an active layer of a semiconductor-on-insulator (SOI) substrate. The substrate 216 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; the like; or combinations thereof. In some embodiments, the substrate 216 may include a ceramic material, a polymer film, a magnetic material, the like, or a combination thereof. Other substrates, such as multi-layered or gradient substrates, may also be used.

The semiconductor die 219 has an active surface (e.g., a signal transmission surface) and a backside surface (e.g., a surface without exposed metal features) opposite to the active surface. The active surface of the semiconductor die 219 is closer to the interconnect structure 218 than the backside surface of the semiconductor die 219. In some embodiments, the semiconductor die 219 includes a logic die or a power management die. The logic die may include a central processing unit (CPU), a graphics processing unit (GPU), a system-on-a-chip (SoC), a component-on-a-wafer (CoW), an application processor (AP), a microcontroller, or the like. The power management die may include a power management integrated circuit (PMIC) die, or the like.

In some embodiments, although not shown, an underfill may fill in the space of the blind hole of the substrate 216 not occupied by the semiconductor die 219 and laterally encapsulate the semiconductor die 219, wherein top surfaces of contact pads (not shown) of the semiconductor die 219 are level or coplanar with the top surface of the underfill to provide a flat surface for forming the interconnect structure 218 and to facilitate the electrical connection between the semiconductor die 219 and the overlying interconnect structure 218.

The interconnect structure 218 interconnects the semiconductor die 219 and the integrated passive device 220 and/or provides electrical routing and connection between via structures 222. The dielectric material layers of the interconnect structure 218 may include low-k dielectric layers. The conductive features of the interconnect structure 218 may include conductive lines and/or conductive vias and may be formed using a suitable process, such as a damascene process.

The integrated passive device 220 includes, for example, an integrated voltage regulator (IVR) or the like to provide desired functionality and performance benefits. By integrate the integrated passive device 220 such as the integrated voltage regulator into the second interconnect component 108, heat dissipation and/or electrical performances of the overlying semiconductor devices (not shown in FIG. 2) may be improved. Specifically, integrated voltage regulators help save power, reduce size, improve transient response, reduce the number of required components and/or save costs; therefore, integrated voltage regulators provide performance, efficiency, size and/or cost advantages for electronic applications, especially energy-intensive, data-intensive electronic applications.

In some embodiments, as shown in FIG. 3, as an example of the integrated voltage regulator, the integrated passive device 220 includes a first cadmium zinc telluride (CZT) layer 300, a first passivation layer 302 disposed on the first cadmium zinc telluride layer 300, a plurality of metal (e.g., copper) patterns 304 embedded in the first passivation layer 302, a second cadmium zinc telluride layer 306 disposed on the first cadmium zinc telluride layer 300 and the first passivation layer 302, and a second passivation layer 308 covering the second cadmium zinc telluride layer 306, and the integrated passive device 220 is electrically connected to the interconnect structure 218 through a plurality of conductive connectors 310.

The first passivation layer 302 and the second passivation layer 308 may be a polymer such as PBO, polyimide, BCB, or the like; a nitride such as silicon nitride or the like; an oxide such as silicon oxide, PSG, BSG, BPSG, or the like; the like, or a combination thereof. The first passivation layer 302 and the second passivation layer 308 may be formed, for example, by spin coating, lamination, chemical vapor deposition (CVD), or the like.

The conductive connectors 310 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 310 may include a conductive material such as solder, copper, aluminum, gold, nickel, silver, palladium, tin, the like, or a combination thereof. In some embodiments, the conductive connectors 310 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 310 includes metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

The via structures 222 are spaced apart from the integrated passive device 220 by a gap. In some embodiments, a width WG of the gap G is larger than or equal to 20 μm and smaller than or equal to 25 μm, and a depth DG of the gap G is larger than 0 μm and smaller than or equal to 40 μm.

In some embodiments, each via structure 222 is a stack of multiple through vias. For example, as shown in FIG. 3, each via structure 222 includes a first through via 312, a second through via 314 and a third through via 316 sequentially disposed on the interconnect structure 218, wherein the first through via 312 and the second through via 314 are embedded in the passivation layer 224, and the third through via 316 is embedded in the encapsulant 226. The first through via 312, the second through via 314 and the third through via 316 may be formed by a method and a material similar to those of the through vias 104.

The passivation layer 224 may be formed by a method and a material similar to those of the first passivation layer 302 and the second passivation layer 308.

The encapsulant 226 is in the gap G and laterally surrounds the integrated passive device 220 and the via structure 226. As shown in FIG. 2, the encapsulant 226, the integrated passive device 220 and the via structure 226 are disposed on a side (e.g., top side) of the interconnect structure 218 that is opposite to the semiconductor die 219.

The encapsulant 226 may include a molding compound (such as a lamination type molding compound (e.g., epoxy)), an anisotropic conductive film, or the like, and the encapsulant 226 may be formed by a lamination process followed by a planarization process (e.g., a mechanical grinding process and/or a chemical mechanical polishing process) to expose the top surface of the via structures 222.

In the case where a high gap G (e.g., greater than 40 μm before the planarization process to expose the top surface of the via structures 222) exists between the integrated passive device 220 and the adjacent via structures 222, voids or bubbles may be generated easily at the interface between the liquid type PI encapsulant (formed by a coating (or filling) process) in the gap G and the underlying component/layer due to significant temperature change during the manufacturing process (e.g., a post reflow process or a ball mount process) and/or reliability test process, thereby causing yield and/or reliability (e.g., delamination or crack) issues. By replacing the liquid type PI coating (or filling) process with the film type molding lamination process, IVR wafer warpage issue can be reduced, a smoother encapsulant top surface (less recesses) can be obtained, a larger process window during the subsequent planarization process (to expose the top surface of the via structures 222) can be obtained, and/or voids or bubbles generated at the interface between the encapsulant 226 in the gap G and the underlying component/layer can be reduced.

Film type (or lamination type) molding compounds (e.g., the encapsulant 226) may have fillers that are smaller in average size and distributed in a more uniform manner (less affected by gravity) than the fillers in liquid type molding compounds (e.g., the encapsulant 210). In other words, the average size (e.g., average particle size S2 shown in FIG. 9; also referred to as “second average size”) of the fillers F2 (shown in FIG. 9; also referred to as “second filler”) of the encapsulant 226 may be smaller than the average size (e.g., average particle size S1 shown in FIG. 9; also referred to as “first average size”) of the fillers F1 (shown in FIG. 9; also referred to as “first filler”) of the encapsulant 210. In some embodiments, the second average size of the second filler is larger than or equal to 1 μm and smaller than or equal to 5 μm, and the first average size of the first filler is larger than 5 μm. For example, the first average size of the first filler is about 25 μm, but not limited thereto.

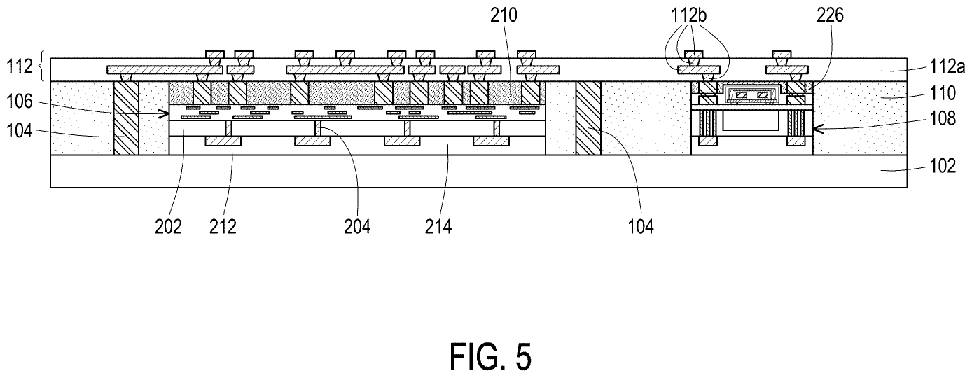

The average thickness AT210 (also referred to as “first average thickness”) of the encapsulant 210 may be different from the average thickness AT226 (also referred to as “second average thickness”) of the encapsulant 226. For example, the average thickness of the encapsulant 210 may be larger than the average thickness of the encapsulant 226. In some embodiments, the thickness of the encapsulant 210 may be 15 μm to 25 μm, and the average thickness AT210 may be about 15 μm, but not limited thereto. In some embodiments, the encapsulant 226 in the gap G has a first thickness T1 and the encapsulant 226 over the integrated passive device 220 has a second thickness T2 smaller than the first thickness T1. In some embodiments, the second thickness T2 is larger than 0 μm and smaller than or equal to 10 μm. The encapsulant 226 over the integrated passive device 220 (i.e., the portion of the encapsulant 226 located between the integrated passive device 220 and a redistribution structure 112 formed in FIG. 5) can help shield the conductive materials over the integrated passive device 220, thereby reducing the parasitic capacitance.

The pads 228 electrically and physically couple the through-substrate via structures 217 and embedded in the encapsulant 230. The pads 228 and the interconnect structure 218 are disposed on opposite sides of the substrate 216, respectively. The pads 228 may be formed by a method and a material similar to those of the through vias 104. The pads 228 electrically couple the respective integrated circuits of the interconnect structure 218 through the through-substrate via structures 217.

The encapsulant 230 may be a molding compound, a molding underfill, a resin (such as an epoxy resin), glue, or the like. In some embodiments, the encapsulation material is formed by an over-molding process, such that not only sidewall surfaces of the pads 228 but also surfaces of the pads 228 away from the substrate 206 are encapsulated/covered by the encapsulant 230. In some embodiments, the encapsulation material is formed by at least one of a compression molding process, an immersion molding process and a transfer molding process. In some embodiments, the encapsulation material may require a curing process. In some embodiments, coefficient of thermal expansion (CTE) of the encapsulant 230 is similar or equal to coefficient of thermal expansion of the encapsulant 226 to improve warpage problem.

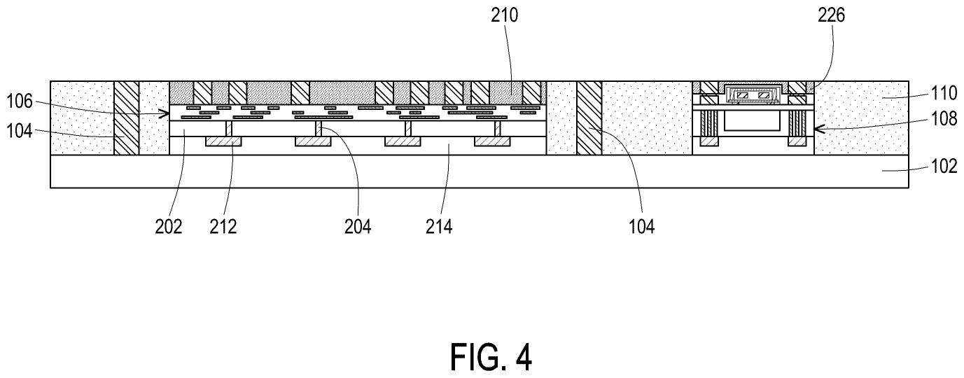

Referring to FIG. 4, an encapsulant 110 is formed on the first carrier substrate 102 and laterally surround the through vias 104, the first interconnect component 106 and the second interconnect component 108. The encapsulant 110 may be formed by a method and a material similar to those of the encapsulant 214. In some embodiments, a planarization process (e.g., a mechanical grinding process and/or a chemical mechanical polishing process) is performed on the cured encapsulant material to expose top surfaces of the through vias 104, top surfaces of the conductive features (e.g., the through vias 208 and the via structures 222 shown in FIG. 2) in the first interconnect component 106 and the second interconnect component 108. After the planarization process, top surfaces of the through vias 104, top surface of the first interconnect component 106 and top surface of the second interconnect component 108 may be level or coplanar with the top surface of the encapsulant 110.

Referring to FIG. 5, a redistribution structure 112 is formed over the encapsulant 110, the through vias 104, the first interconnect component 106 and the second interconnect component 108. The redistribution structure 112 includes dielectric material layers 112a and conductive features 112b embedded in or formed on the dielectric material layers 112a. The conductive features 112b may also be referred to as redistribution layers or redistribution lines. The redistribution structure 112 is shown as an example having two layers of conductive features. More or fewer dielectric material layers and conductive features may be formed in the redistribution structure 112. If fewer dielectric material layers and conductive features are to be formed, steps and process discussed below may be omitted. If more dielectric material layers and conductive features are to be formed, steps and processes discussed below may be repeated.

As an example of forming the redistribution structure 112, a first dielectric layer (not shown) within the dielectric material layers 112 a is deposited on the encapsulant 110, the through vias 104, the first interconnect component 106 and the second interconnect component 108. In some embodiments, the first dielectric layer is formed of a photo-sensitive material such as PBO, polyimide, BCB, or the like, which may be patterned using a lithography mask. The first dielectric layer may be formed by spin coating, lamination, CVD, the like, or a combination thereof. The first dielectric layer is then patterned. The patterning forms openings exposing portions of the conductive features (e.g., the through vias 208 and the via structures 222 shown in FIG. 2) in the first interconnect component 106 and the second interconnect component 108. The patterning may be by an acceptable process, such as by exposing and developing the first dielectric layer to light when the first dielectric layer is a photo-sensitive material or by etching using, for example, an anisotropic etch.

A first layer of conductive features 112b is then formed. The first layer of conductive features 112b includes portions on and extending along the major surface of the first dielectric layer. The first layer of conductive features 112b further includes portions extending through the first dielectric layer to physically and electrically couple the conductive features (e.g., the through vias 208 and the via structures 222 shown in FIG. 2) in the first interconnect component 106 and the second interconnect component 108. As an example to form the first layer of conductive features 112b, a seed layer is formed over the first dielectric layer and in the openings of the first dielectric layer. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the first layer of conductive features 112b. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the first layer of conductive features 112b. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

A second dielectric layer (not shown) within the dielectric material layers 112a is deposited on the first dielectric layer and the first layer of conductive features 112b. The second dielectric layer may be formed in a manner similar to the first dielectric layer, and may be formed of a similar material as the first dielectric layer.

A second layer of conductive features 112b is then formed. The second layer of conductive features 112b includes portions on and extending along the major surface of the second dielectric layer. The second layer of conductive features 112b further includes portions extending through the second dielectric layer to physically and electrically couple the first layer of conductive features 112b. The second layer of conductive features 112b may be formed in a similar manner and of a similar material as the first layer of conductive features 112b. In some embodiments, the second layer of conductive features 112b has a different size and/or pitch than the first layer of conductive features 112b.

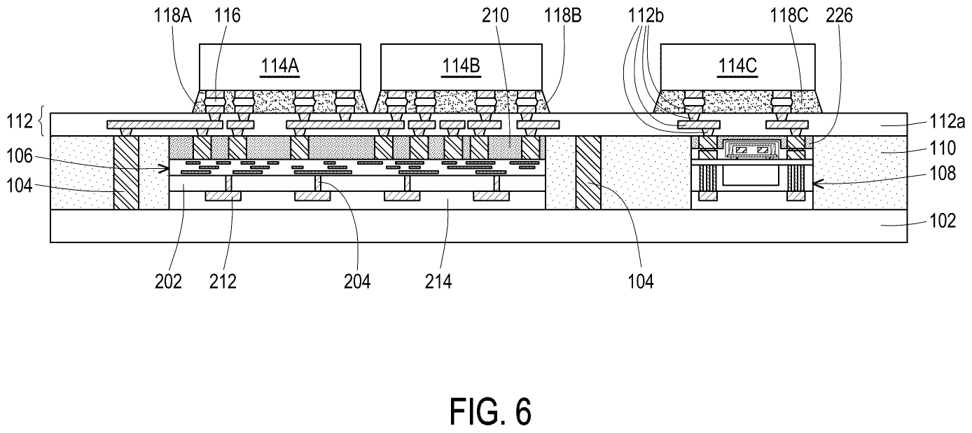

Referring to FIG. 6, a plurality of semiconductor devices (e.g., a first semiconductor device 114A, a second semiconductor device 114B and a third semiconductor device 114C) are bonded to the redistribution structure 112 through a plurality of conductive connectors 116. For example, the first semiconductor device 114A, the second semiconductor device 114B and the third semiconductor device 114C are physically and electrically connected to the plurality of conductive connectors 116 to make electrical connection between the plurality of semiconductor devices and the redistribution structure 112.

FIG. 6 shows the attachment of three semiconductor devices, but in other embodiments, one, two, or more than three semiconductor devices may be attached to the conductive connectors 116. In some embodiments, the semiconductor devices attached to the conductive connectors 116 may include more than one of the same type of semiconductor device or may include two or more different types of semiconductor devices. The semiconductor devices may be attached in a different arrangement or configuration than shown. For example, FIG. 6 shows the first semiconductor device 114A is electrically connected to the second semiconductor device 114B through the redistribution structure 112 and the first interconnect component 106, and the third semiconductor device 114C is electrically connected to the second interconnect component 108, but in other embodiments each semiconductor device may be electrically connected to a single interconnect structure.

The semiconductor devices may be placed on the conductive connectors 116 using a suitable process such as a pick-and-place process. The semiconductor devices may be placed such that conductive regions of the semiconductor devices (e.g., contact pads, conductive connectors, solder bumps, or the like) are aligned with corresponding conductive connectors 116 on the redistribution structure 112. Once in physical contact, a reflow process may be utilized to bond the conductive connectors 116 to the semiconductor devices. The process shown in FIG. 1 through FIG. 6 is a “chip-first” process in which the semiconductor devices are attached before the core substrate (e.g., a circuit substrate; not shown) is attached. In other embodiments, the semiconductor devices are attached after the core substrate is attached.

As shown in FIG. 6, a plurality of underfills (e.g., a first underfill 118A, a second underfill 118B and a third underfill 118C) may be deposited between the plurality of semiconductor devices and the redistribution structure 112. In some alternative embodiments, a single underfill may be deposited between the plurality of semiconductor devices and the redistribution structure 112. The plurality of underfills may be a material such as a molding compound, an epoxy, an underfill, a molding underfill (MUF), a resin, or the like.

By forming the interconnect components (e.g., the first interconnect component 106 and the second interconnect component 108) in the interconnect structure that is close to the semiconductor devices, the routing distances of connections between the semiconductor devices may be reduced, which can increase the bandwidth or speed of electrical signals communicated between the semiconductor devices, improving high-speed operation. In this manner, the interconnect components can increase the communication bandwidth between the semiconductor devices while maintaining low contact resistance and high reliability. Additionally, the greater routing density available in the interconnect components can provide more efficient routing between semiconductor devices, and in some cases can reduce the number of conductive features used in the interconnect structures or the number of conductive features used in the core substrate. In some cases, forming an interconnect structure with an IPD (e.g., the integrated passive device 220 in FIG. 2 or FIG. 3) can reduce the routing distance of connections between the semiconductor device (e.g., the third semiconductor device 114C) and the IPD, which can improve high-speed operation.

Each of the semiconductor devices may include one or more an integrated fan-out (InFO) structures, semiconductor packages, integrated circuit dies, such as a logic die (e.g., central processing unit (CPU), graphics processing unit (GPU), system-on-a-chip (SoC), component-on-a-wafer (CoW), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), an input-output (I/O) die, the like, or combinations thereof. The integrated circuit dies may include a memory device such as a hybrid memory cube (HMC) module, a high bandwidth memory (HBM) module, or the like that includes multiple memory dies. In some embodiments, one or more of the semiconductor devices includes integrated circuit devices, such as transistors, capacitors, inductors, resistors, metallization layers, external connectors, and the like, therein, as desired for a particular functionality. In some embodiments, the first semiconductor device 114A includes a logic die such as system-on-a-chip, and the second semiconductor device 114B and the third semiconductor device 114C include memory dies or memory devices.

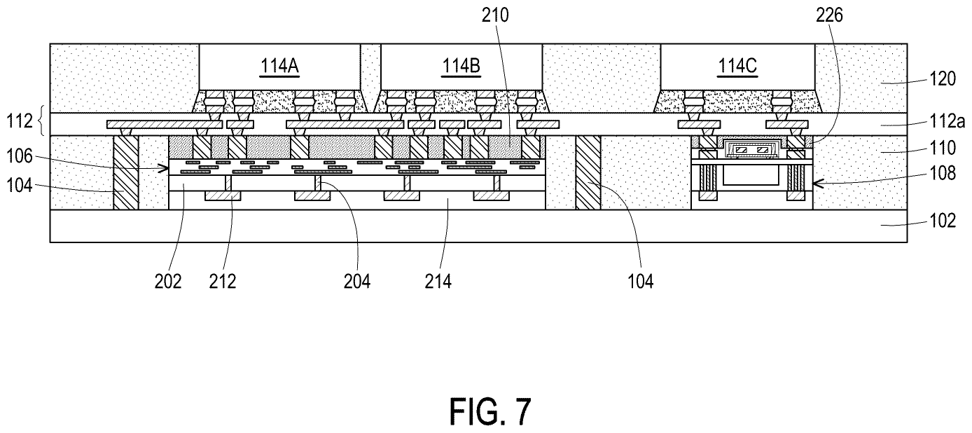

Referring to FIG. 7, an encapsulant 120 is formed on the redistribution structure 112 and laterally surround the semiconductor devices and the underfills. The encapsulant 120 may be formed by a method and a material similar to those of the encapsulant 110. In some embodiments, a planarization process (e.g., a mechanical grinding process and/or a chemical mechanical polishing process) is performed on the cured encapsulant material to expose top surfaces of the semiconductor devices. After the planarization process, top surfaces of the semiconductor devices may be level or coplanar with the top surface of the encapsulant 120.

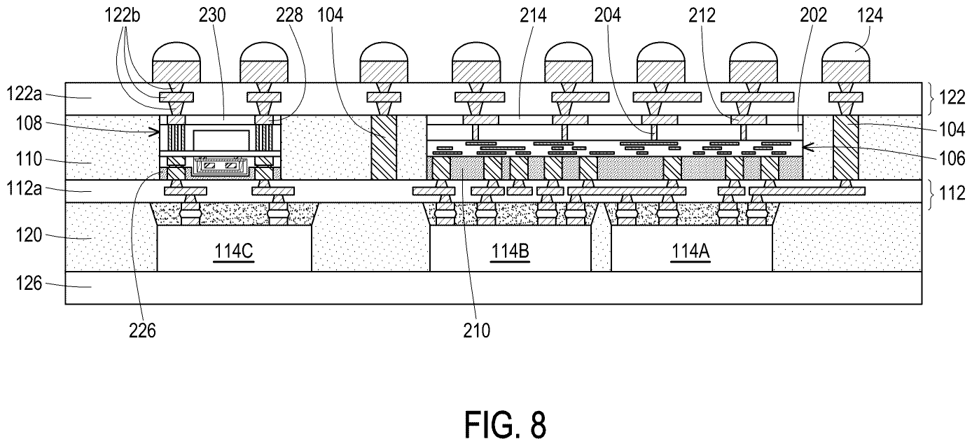

Referring to FIG. 8, the structure is de-bonded. The de-bonding is performed to detach (or “de-bond”) the first carrier substrate 102 from the structure. In some embodiments, the de-bonding includes projecting a light such as a laser light or an UV light on the release layer (not shown) so that the release layer decomposes under the heat of the light and the first carrier substrate 102 can be removed. The structure is then flipped over and attached to a second carrier substrate 126. The second carrier substrate 126 may be similar to the first carrier substrate 102 or may be, for example, a tape. A release layer (not shown) may be formed on the second carrier substrate 126 to facilitate attachment of the structure to the second carrier substrate 126. The release layer may be similar to the release layer mentioned in the description corresponding to FIG. 1 or may be, for example, an adhesive layer.

After attachment to the second carrier substrate 126, a planarization process (e.g., a mechanical grinding process and/or a chemical mechanical polishing process) is performed on the encapsulant 110, the through vias 104, the encapsulant 214 of the first interconnect component 106 and the encapsulant 230 of the second interconnect component 108 to expose top surfaces of the conductive features (e.g., the pads 212 and the pads 228) in the first interconnect component 106 and the second interconnect component 108. After the planarization process, top surfaces of the through vias 104, top surfaces of the pads 212 in the first interconnect component 106 and top surfaces of the pads 228 in the second interconnect component 108 may be level or coplanar with the top surface of the encapsulant 110.

A redistribution structure 122 is then formed over the encapsulant 110, the through vias 104, the first interconnect component 106 and the second interconnect component 108 (the encapsulant 110, the through vias 104, the first interconnect component 106 and the second interconnect component 108 as a whole may be referred to as an “interconnect package”), wherein the redistribution structure 122 and the redistribution structure 112 are on opposite sides of the interconnect package, respectively.

The redistribution structure 122 includes dielectric material layers 122a and conductive features 122b embedded in or formed on the dielectric material layers 122a. The conductive features 122b may also be referred to as redistribution layers or redistribution lines. The redistribution structure 122 is shown as an example having two layers of conductive features. More or fewer dielectric material layers and conductive features may be formed in the redistribution structure 122. The redistribution structure 122 may be formed by a method and a material similar to those of the redistribution structure 112.

A plurality of conductive connectors 124 are formed on the redistribution structure 122. The conductive connectors 124 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 124 may include a conductive material such as solder, copper, aluminum, gold, nickel, silver, palladium, tin, the like, or a combination thereof. In some embodiments, the conductive connectors 124 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 124 include metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

Referring to FIG. 9, the structure is de-bonded. The de-bonding is performed to detach (or “de-bond”) the second carrier substrate 126 from the structure. In some embodiments, the de-bonding includes projecting a light such as a laser light or an UV light on the release layer (not shown) so that the release layer decomposes under the heat of the light and the second carrier substrate 126 can be removed. The structure is then flipped over and attached to a third carrier substrate (not shown). The third carrier substrate may be a tape. In some embodiments, although not shown, a planarization process (e.g., a mechanical grinding process and/or a chemical mechanical polishing process) is performed on the exposed top surfaces of the semiconductor devices and the exposed top surface of the encapsulant 120. In some embodiments, although not shown, the structure is flipped over and mounted to a dicing frame, and then a singulation process is performed by sawing along scribe line regions (not shown) to form multiple singulated structures, as shown in FIG. 9. In some embodiments, the singulated structure is bonded on a core substrate (not shown). In some embodiments, a lid (not shown) for heat dissipation is attached to the core substrate to enclose the singulated structure.

As shown in FIG. 9, a semiconductor package 1 may include a PoP device, wherein a top semiconductor package is stacked on top of a bottom semiconductor package to provide a high level of integration and component density. In FIG. 9, the through-substrate via structures 204 in the substrate 202 is indirectly connected to the conductive features 122b of the redistribution structure 122 through the pads 212. The pads can increase the contact area with the conductive features 122b of the redistribution structure 122, which can reduce open circuit or crack issues and increase the reliability. However, in other embodiments, as shown in semiconductor package 1′ in FIG. 10, the through-substrate via structures 204 in the substrate 202 can be directly connected to the conductive features 122b of the redistribution structure 122, and the pads 212 and the encapsulant 214 can be omitted.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor package includes a first interconnect component, a second interconnect component and a third encapsulant. The first interconnect component includes a first encapsulant. The second interconnect component is laterally spaced apart from the first interconnect component and includes a second encapsulant. The third encapsulant laterally encapsulates the first interconnect component and the second interconnect component. The first encapsulant includes a first filler having a first average size, and the second encapsulant includes a second filler having a second average size different from the first average size.

In some embodiments, the second interconnect component further includes an integrated passive device and a via structure spaced apart from the integrated passive device by a gap, wherein the second encapsulant is in the gap and laterally surrounds the integrated passive device and the via structure.

In some embodiments, a width of the gap is larger than or equal to 20 μm and smaller than or equal to 25 μm, and a depth of the gap is larger than 0 μm and smaller than or equal to 40 μm.

In some embodiments, the second interconnect component further includes an interconnect structure and a semiconductor die. The second encapsulant, the integrated passive device and the via structure are disposed on a side of the interconnect structure that is opposite to the semiconductor die.

In some embodiments, the integrated passive device includes an integrated voltage regulator, and the semiconductor die includes a logic die or a power management die.

In some embodiments, the first encapsulant includes a liquid type molding compound, the second encapsulant includes a lamination type molding compound, and the second average size of the second filler is smaller than the first average size of the first filler.

In some embodiments, the second average size of the second filler is larger than or equal to 1 μm and smaller than or equal to 5 μm, and the first average size of the first filler is larger than 5 μm.

According to some embodiments, a semiconductor package includes a first interconnect component, a second interconnect component and a third encapsulant. The first interconnect component includes a first encapsulant. The second interconnect component is laterally spaced apart from the first interconnect component and includes a second encapsulant. The third encapsulant laterally encapsulates the first interconnect component and the second interconnect component. The first encapsulant has a first average thickness, and the second encapsulant has a second average thickness different from the first average thickness.

In some embodiments, the second interconnect component further includes an integrated passive device and a via structure spaced apart from the integrated passive device by a gap, wherein the second encapsulant is in the gap and laterally surrounds the integrated passive device and the via structure.

In some embodiments, the second encapsulant in the gap has a first thickness and the second encapsulant over the integrated passive device has a second thickness smaller than the first thickness.

In some embodiments, the second thickness is larger than 0 μm and smaller than or equal to 10 μm.

In some embodiments, a width of the gap is larger than or equal to 20 μm and smaller than or equal to 25 μm, and a depth of the gap is larger than 0 μm and smaller than or equal to 40 μm.

In some embodiments, the second interconnect component further includes an interconnect structure and a semiconductor die. The second encapsulant, the integrated passive device and the via structure are disposed on a side of the interconnect structure that is opposite to the semiconductor die.

In some embodiments, the integrated passive device includes an integrated voltage regulator, and the semiconductor die includes a logic die or a power management die.

In some embodiments, the first encapsulant includes a liquid type molding compound, the second encapsulant includes a lamination type molding compound, and the second average thickness of the second encapsulant is smaller than the first average thickness of the first encapsulant.

According to some embodiments, a semiconductor package includes a first interconnect component, a second interconnect component, a third encapsulant and a redistribution structure. The first interconnect component includes a first encapsulant. The second interconnect component is laterally spaced apart from the first interconnect component and includes a second encapsulant and an integrated passive device surrounded by the second encapsulant. The third encapsulant laterally encapsulates the first interconnect component and the second interconnect component. The redistribution structure is disposed on the first interconnect component, the second interconnect component and the third encapsulant. A portion of the second encapsulant is located between the integrated passive device and the redistribution structure.

In some embodiments, the integrated passive device includes an integrated voltage regulator.

In some embodiments, a thickness of the second encapsulant located between the integrated passive device and the redistribution structure is larger than 0 μm and smaller than or equal to 10 μm.

In some embodiments, the second interconnect component further includes a via structure spaced apart from the integrated passive device by a gap, wherein the second encapsulant is in the gap and laterally surrounds the integrated passive device and the via structure.

In some embodiments, the second encapsulant in the gap has a first thickness and the second encapsulant located between the integrated passive device and the redistribution structure has a second thickness smaller than the first thickness.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first interconnect component comprising a first encapsulant;
a second interconnect component laterally spaced apart from the first interconnect component and comprising a second encapsulant; and
a third encapsulant laterally encapsulating the first interconnect component and the second interconnect component;
wherein the first encapsulant comprises a first filler having a first average size, and the second encapsulant comprises a second filler having a second average size different from the first average size.

2. The semiconductor package as claimed in claim 1, wherein the second interconnect component further comprises:
an integrated passive device; and
a via structure spaced apart from the integrated passive device by a gap,
wherein the second encapsulant is in the gap and laterally surrounds the integrated passive device and the via structure.

3. The semiconductor package as claimed in claim 2, wherein:
a width of the gap is larger than or equal to 20 μm and smaller than or equal to 25 μm, and
a depth of the gap is smaller than or equal to 40 μm.

4. The semiconductor package as claimed in claim 2, wherein the second interconnect component further comprises:
an interconnect structure; and
a semiconductor die,
wherein the second encapsulant, the integrated passive device and the via structure are disposed on a side of the interconnect structure that is opposite to the semiconductor die.

5. The semiconductor package as claimed in claim 4, wherein:
the integrated passive device comprises an integrated voltage regulator, and
the semiconductor die comprises a logic die or a power management die.

6. The semiconductor package as claimed in claim 1, wherein:
the first encapsulant comprises a liquid type molding compound,
the second encapsulant comprises a lamination type molding compound, and
the second average size of the second filler is smaller than the first average size of the first filler.

7. The semiconductor package as claimed in claim 6, wherein:
the second average size of the second filler is larger than or equal to 1 μm and smaller than or equal to 5 μm, and
the first average size of the first filler is larger than 5 μm.

8. A semiconductor package, comprising:
a first interconnect component comprising a first encapsulant;
a second interconnect component laterally spaced apart from the first interconnect component and comprising a second encapsulant; and
a third encapsulant laterally encapsulating the first interconnect component and the second interconnect component;
wherein the first encapsulant has a first average thickness, and the second encapsulant has a second average thickness different from the first average thickness.

9. The semiconductor package as claimed in claim 8, wherein the second interconnect component further comprises:
an integrated passive device; and
a via structure spaced apart from the integrated passive device by a gap,
wherein the second encapsulant is in the gap and laterally surrounds the integrated passive device and the via structure.

10. The semiconductor package as claimed in claim 9, wherein the second encapsulant in the gap has a first thickness and the second encapsulant over the integrated passive device has a second thickness smaller than the first thickness.

11. The semiconductor package as claimed in claim 10, wherein the second thickness is smaller than or equal to 10 μm.

12. The semiconductor package as claimed in claim 9, wherein:
a width of the gap is larger than or equal to 20 μm and smaller than or equal to 25 μm, and
a depth of the gap is smaller than or equal to 40 μm.

13. The semiconductor package as claimed in claim 9, wherein the second interconnect component further comprises:
an interconnect structure; and
a semiconductor die,
wherein the second encapsulant, the integrated passive device and the via structure are disposed on a side of the interconnect structure that is opposite to the semiconductor die.

14. The semiconductor package as claimed in claim 13, wherein:
the integrated passive device comprises an integrated voltage regulator, and
the semiconductor die comprises a logic die or a power management die.

15. The semiconductor package as claimed in claim 8, wherein:
the first encapsulant comprises a liquid type molding compound,
the second encapsulant comprises a lamination type molding compound, and
the second average thickness of the second encapsulant is smaller than the first average thickness of the first encapsulant.

16. A semiconductor package, comprising:
a first interconnect component comprising a first encapsulant;
a second interconnect component laterally spaced apart from the first interconnect component and comprising a second encapsulant and an integrated passive device surrounded by the second encapsulant;
a third encapsulant laterally encapsulating the first interconnect component and the second interconnect component; and
a redistribution structure disposed on the first interconnect component, the second interconnect component and the third encapsulant,
wherein a portion of the second encapsulant is located between the integrated passive device and the redistribution structure.

17. The semiconductor package as claimed in claim 16, wherein the integrated passive device comprises an integrated voltage regulator.

18. The semiconductor package as claimed in claim 17, wherein a thickness of the second encapsulant located between the integrated passive device and the redistribution structure is smaller than or equal to 10 μm.

19. The semiconductor package as claimed in claim 16, wherein the second interconnect component further comprises:
a via structure spaced apart from the integrated passive device by a gap,
wherein the second encapsulant is in the gap and laterally surrounds the integrated passive device and the via structure.

20. The semiconductor package as claimed in claim 19, wherein the second encapsulant in the gap has a first thickness and the second encapsulant located between the integrated passive device and the redistribution structure has a second thickness smaller than the first thickness.
